(19) United States
(12) Patent Application Publication
(10) Pub. No.: US 2026/0039261 A1
(43) Pub. Date: Feb. 5, 2026

(54) NON-PERIODIC DIGITAL ENVELOPE TRACKING FOR POWER AMPLIFIERS

(71) Applicant: Samsung Electronics Co., Ltd., Suwon-si (KR)

(72) Inventors: Masoud Shahshahani, Allen, TX (US); Chance Anthony Tarver, Arlington, TX (US); Matthew Tonnemacher, Allen, TX (US); Gang Xu, Allen, TX (US)

(21) Appl. No.: 19/187,961

(22) Filed: Apr. 23, 2025

Related U.S. Application Data
(60) Provisional application No. 63/678,352, filed on Aug. 1, 2024.

(51) Int. Cl. H03F 3/213

(52) U.S. Cl. CPC H03F 3/213; H03F 2200/102; H03F 2200/336; H03F 2200/451

(57) ABSTRACT

Methods and systems for non-periodic digital envelope tracking for power amplifiers. A method includes setting a default digital envelope tracking (DET) level in a DET level module of a Faster-than-Symbol Power Tracking (FSPT) module and receiving baseband data using the FSPT module. The method also includes calculating an input signal amplitude using the DET level module based on the received IQ baseband data and processing the IQ baseband data using a low power search (LPS) module to produce an LPS output. The method further includes generating a DET signal using a DET decision module based on the input signal amplitude and the LPS output. The DET decision module is configured to use non-periodic DET to generate the DET signal. The method includes providing the DET signal to a supply modulator to drive a power amplifier.

### TECHNICAL FIELD

The present application claims priority to U.S. Provisional Patent Application No. 63/678,352, filed on Aug. 1, 2024. The contents of the above-identified patent documents are incorporated herein by reference.

### TECHNICAL FIELD

The present disclosure relates generally to wireless communication systems. More specifically, the present disclosure relates to a system and method for non-periodic digital envelope tracking for power amplifiers.

### BACKGROUND

In 6G extreme-MIMO systems, there are likely to be hundreds of power amplifiers in a single base station. These power amplifiers typically consume the majority of the power budget of the base station. Moreover, their power-added efficiency (PAE is often as low as 20%. The lower PAE is indicative of wasted power that contributes significantly to thermal concerns and increases the operational expenditure costs of a system. One potential solution to improve PA E is Digital Envelope Tracking (DET), which dynamically adjusts the bias voltage based on the instantaneous baseband-signal envelope. When the envelope power decreases, the bias voltage is also reduced, resulting in power savings. However, the transition and settling time associated with changing the supply voltage of power amplifiers can momentarily disrupt the power amplifier output signal. As the DET switching frequency increases, signal quality degradation becomes a significant concern.

Accordingly, there is a need for systems and methods for improved digital pre-distortion for digital envelope tracking systems that overcome these challenges.

### SUMMARY

The present disclosure relates to a system and method for non-periodic digital envelope tracking for power amplifiers.

In one embodiment, a method is provided. The method includes setting a default digital envelope tracking (DET) level in a DET level module of a Faster-than-Symbol Power Tracking (FSPT) module and receiving in-phase and quadrature (IQ) baseband data in an input signal using the FSPT module. The method also includes calculating an input signal amplitude using the DET level module of the FSPT module based on the received IQ baseband data and processing the IQ baseband data using a low power search (LPS) module of the FSPT module to produce an LPS output. The method further includes generating a DET signal using a DET decision module of the FSPT module based on the input signal amplitude and the LPS output. The DET decision module is configured to use non-periodic DET to generate the DET signal. The method includes providing the DET signal to a supply modulator to drive a power amplifier.

In another embodiment, an electronic device is provided. The electronic device includes a power amplifier, and a processor operably coupled to the power amplifier. The processor is configured to cause the electronic device to set a default digital envelope tracking (DET) level in a DET level module of a Faster-than-Symbol Power Tracking (FSPT) module and receive in-phase and quadrature (IQ) baseband data in an input signal using the FSPT module. The processor is also configured to cause the electronic device to calculate an input signal amplitude using the DET level module of the FSPT module based on the received IQ baseband data and process the IQ baseband data using a low power search (LPS) module of the FSPT module to produce an LPS output. The processor is further configured to cause the electronic device to generate a DET signal using a DET decision module of the FSPT module based on the input signal amplitude and the LPS output. The DET decision module is configured to use non-periodic DET to generate the DET signal. The processor is also configured to cause the electronic device to provide the DET signal to a supply modulator to drive the power amplifier.

In yet another embodiment, a non-transitory computer-readable medium is provided. The non-transitory computer-readable medium includes program code, that when executed by at least one processor of an electronic device, causes the electronic device to set a default digital envelope tracking (DET) level in a DET level module of a Faster-than-Symbol Power Tracking (FSPT) module and receive in-phase and quadrature (IQ) baseband data in an input signal using the FSPT module. The program code, that when executed by at least one processor of an electronic device, also causes the electronic device to calculate an input signal amplitude using the DET level module of the FSPT module based on the received IQ baseband data and process the IQ baseband data using a low power search (LPS) module of the FSPT module to produce an LPS output. The program code, that when executed by at least one processor of an electronic device, further causes the electronic device to generate a DET signal using a DET decision module of the FSPT module based on the input signal amplitude and the LPS output. The DET decision module is configured to use non-periodic DET to generate the DET signal. The program code, that when executed by at least one processor of an electronic device, also causes the electronic device to provide the DET signal to a supply modulator to drive a power amplifier.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below may be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data may be permanently stored and media where data may be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example wireless network according to embodiments of the present disclosure;

FIG. 2 illustrates an example gNB according to embodiments of the present disclosure;

FIG. 3 illustrates an example UE according to embodiments of the present disclosure;

FIG. 4 illustrates an example signal envelope of a power amplifier;

FIG. 5A illustrates an example non-periodic digital envelope tracking system according to embodiments of the present disclosure;

FIG. 5B illustrates an example flow chart for digital envelope tracking calculation for the non-periodic digital envelope tracking system of FIG. 5A according to embodiments of the present disclosure;

FIG. 6 illustrates an example multi-carrier non-periodic digital envelope tracking system according to embodiments of the present disclosure; and

FIG. 7 illustrates an example method of non-periodic digital envelope tracking according to embodiments of the present disclosure.

### DETAILED DESCRIPTION

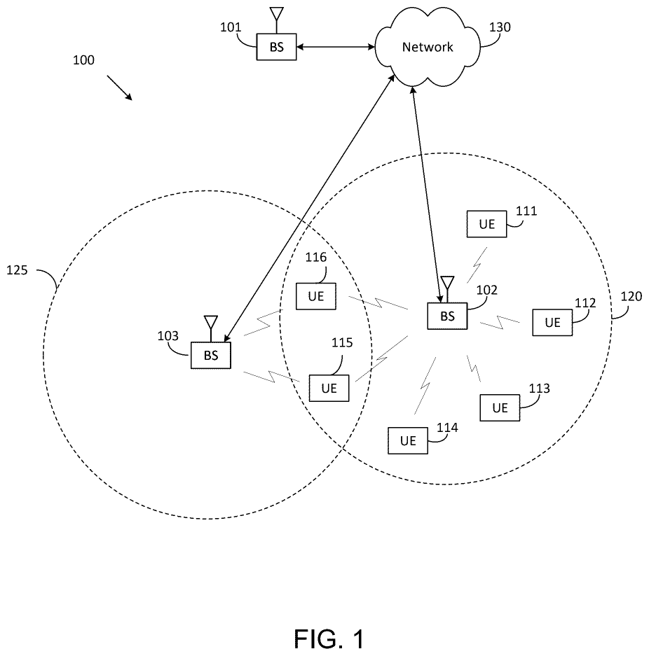

FIGS. 1-7, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

As introduced above, power amplifiers typically consume the majority of the power budget of the base station. While it is convenient to model power amplifiers as having a fixed gain, there is a nonlinear relationship between input and output power. As the input power increases, a fixed gain is not perfectly maintained. Power amplifiers are also highly nonlinear and exhibit memory effects. The power amplifier nonlinearity may harm the error vector magnitude (EVM) of a signal. Moreover, the nonlinearity may create spectral regrowth around the main carrier. This out-of-band emission is limited to an adjacent channel leakage ratio (ACLR) of −45 dBc in many 3GPP-based standards. To achieve this, most transmitters deploy digital pre-distortion (DPD), where the inverse nonlinearity of the power amplifier is used so that the cascade of DPD and the power amplifier is linearized.

Another method used to increase PAE is digital envelope tracking (DET), which dynamically adjusts the bias voltage based on the instantaneous baseband-signal envelope. When the envelope power decreases, the bias voltage is also reduced, resulting in power savings. However, the transition and settling time associated with changing the supply voltage of power amplifiers may momentarily disrupt the power amplifier output signal. As the DET switching frequency increases, signal quality degradation becomes a significant concern.

Additionally, conventional DPD techniques assume static power amplifier nonlinearity, not effectively addressing the challenges in DET power amplifier linearization. While DPD is used to linearize power amplifier functionality, modeling and linearizing power amplifier around the transition time is still a significant challenge. Each transition may require a dedicated DPD model, which increases DPD modeling complexity in combination with the number of DET levels.

Accordingly, the present disclosure provides systems and methods for non-periodic digital envelope tracking for power amplifiers. As described herein, the present disclosure includes a DET level calculator and a DET decision module that is refined based on a Low Power Search algorithm to adjust supply voltages provided to a power amplifier, such as when the input power is low, to reduce power consumption of the power amplifier.

To meet the demand for wireless data traffic having increased since deployment of 4G communication systems and to enable various vertical applications, 5G/NR communication systems have been developed and are currently being deployed. The 5G/NR communication system is considered to be implemented in higher frequency (mmWave) bands, e.g., 28 GHz or 60 GHz bands, so as to accomplish higher data rates or in lower frequency bands, such as 6 GHZ, to enable robust coverage and mobility support. To decrease propagation loss of the radio waves and increase the transmission distance, the beamforming, massive multiple-input multiple-output (MIMO), full dimensional MIMO (FD-MIMO), array antenna, an analog beam forming, large scale antenna techniques are discussed in 5G/NR communication systems.

In addition, in 5G/NR communication systems, development for system network improvement is under way based on advanced small cells, cloud radio access networks (RANs), ultra-dense networks, device-to-device (D2D) communication, wireless backhaul, moving network, cooperative communication, coordinated multi-points (CoMP), reception-end interference cancelation and the like.

The discussion of 5G systems and frequency bands associated therewith is for reference as certain embodiments of the present disclosure may be implemented in 5G systems. However, the present disclosure is not limited to 5G systems or the frequency bands associated therewith, and embodiments of the present disclosure may be utilized in connection with any frequency band. For example, aspects of the present disclosure may also be applied to deployment of 5G communication systems, 6G or even later releases which may use terahertz (THz) bands.

FIGS. 1-3 below describe various embodiments implemented in wireless communications systems and with the use of orthogonal frequency division multiplexing (OFDM) or orthogonal frequency division multiple access (OFDMA) communication techniques. The descriptions of FIGS. 1-3 are not meant to imply physical or architectural limitations to the manner in which different embodiments may be implemented. Different embodiments of the present disclosure may be implemented in any suitably arranged communications system.

FIG. 1 illustrates an example wireless network according to embodiments of the present disclosure. The embodiment of the wireless network shown in FIG. 1 is for illustration only. Other embodiments of the wireless network 100 could be used without departing from the scope of this disclosure.

As shown in FIG. 1, the wireless network includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipment (UEs) within a coverage area 120 of the gNB 102. The first plurality of UEs includes a UE 111, which may be located in a small business; a UE 112, which may be located in an enterprise; a UE 113, which may be a Wifi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3^{rd} generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

Dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

Although FIG. 1 illustrates one example of a wireless network, various changes may be made to FIG. 1. For example, the wireless network could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

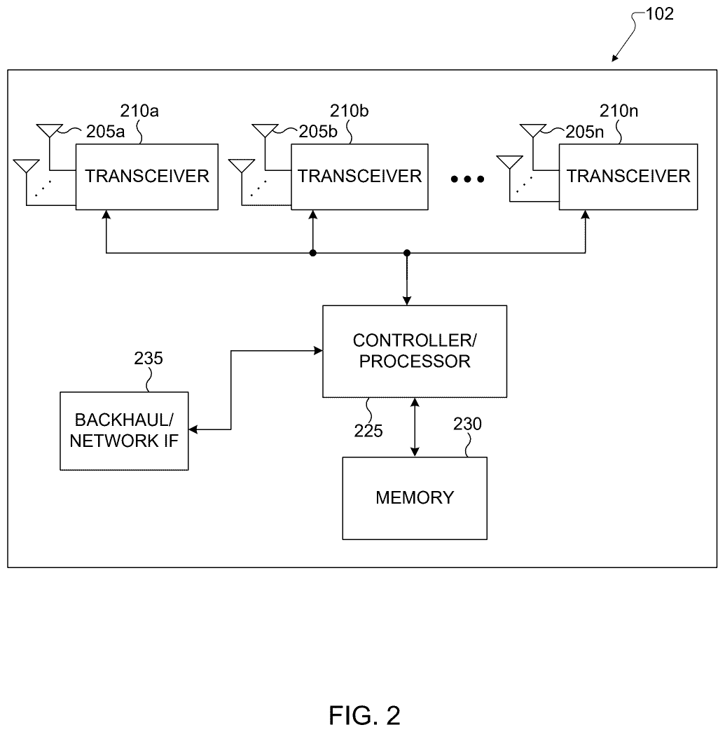

FIG. 2 illustrates an example gNB 102 according to embodiments of the present disclosure. The embodiment of the gNB 102 illustrated in FIG. 2 is for illustration only, and the gNBs 101 and 103 of FIG. 1 could have the same or similar configuration. However, gNBs come in a wide variety of configurations, and FIG. 2 does not limit the scope of this disclosure to any particular implementation of a gNB.

As shown in FIG. 2, the gNB 102 includes multiple antennas 205a-205n, multiple transceivers 210a-210n, a controller/processor 225, a memory 230, and a backhaul or network interface 235.

The transceivers 210a-210n receive, from the antennas 205a-205n, incoming RF signals, such as signals transmitted by UEs in the network 100. The transceivers 210a-210n down-convert the incoming RF signals to generate IF or baseband signals. The IF or baseband signals are processed by receive (RX) processing circuitry in the transceivers 210a-210n and/or controller/processor 225, which generates processed baseband signals by filtering, decoding, and/or digitizing the baseband or IF signals. The controller/processor 225 may further process the baseband signals.

Transmit (TX) processing circuitry in the transceivers 210a-210n and/or controller/processor 225 receives analog or digital data (such as voice data, web data, e-mail, or interactive video game data) from the controller/processor 225. The TX processing circuitry encodes, multiplexes, and/or digitizes the outgoing baseband data to generate processed baseband or IF signals. The transceivers 210a-210n up-converts the baseband or IF signals to RF signals that are transmitted via the antennas 205a-205n.

The controller/processor 225 can include one or more processors or other processing devices that control the overall operation of the gNB 102. For example, the controller/processor 225 could control the reception of UL channel signals and the transmission of DL channel signals by the transceivers 210a-210n in accordance with well-known principles. The controller/processor 225 could support additional functions as well, such as more advanced wireless communication functions. For instance, the controller/processor 225 could support beam forming or directional routing operations in which outgoing/incoming signals from/to multiple antennas 205a-205n are weighted differently to effectively steer the outgoing signals in a desired direction. Any of a wide variety of other functions could be supported in the gNB 102 by the controller/processor 225.

The controller/processor 225 is also capable of executing programs and other processes resident in the memory 230, such as an OS. The controller/processor 225 can move data into or out of the memory 230 as required by an executing process.

The controller/processor 225 is also coupled to the backhaul or network interface 235. The backhaul or network interface 235 allows the gNB 102 to communicate with other devices or systems over a backhaul connection or over a network. The network interface 235 could support communications over any suitable wired or wireless connection(s). For example, when the gNB 102 is implemented as part of a cellular communication system (such as one supporting 5G/NR, LTE, or LTE-A), the interface 235 could allow the gNB 102 to communicate with other gNBs over a wired or wireless backhaul connection. When the gNB 102 is implemented as an access point, the network interface 235 could allow the gNB 102 to communicate over a wired or wireless local area network or over a wired or wireless connection to a larger network (such as the Internet). The interface 235 includes any suitable structure supporting communications over a wired or wireless connection, such as an Ethernet or transceiver.

The memory 230 is coupled to the controller/processor 225. Part of the memory 230 could include a RAM, and another part of the memory 230 could include a Flash memory or other ROM.

Although FIG. 2 illustrates one example of gNB 102, various changes may be made to FIG. 2. For example, the gNB 102 could include any number of each component shown in FIG. 2. Also, various components in FIG. 2 could be combined, further subdivided, or omitted and additional components could be added according to particular needs.

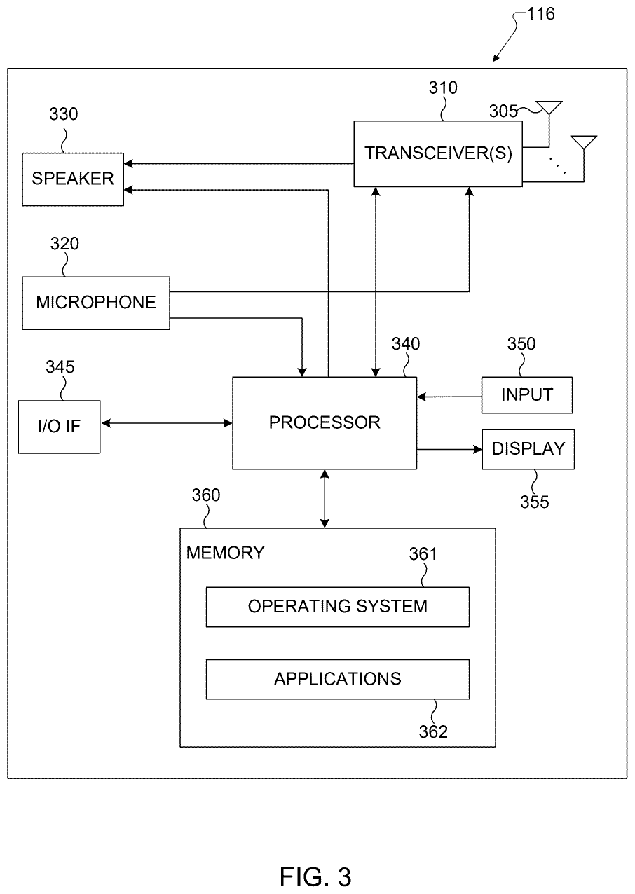

FIG. 3 illustrates an example UE 116 according to embodiments of the present disclosure. The embodiment of the UE 116 illustrated in FIG. 3 is for illustration only, and the UEs 111-115 of FIG. 1 could have the same or similar configuration. However, UEs come in a wide variety of configurations, and FIG. 3 does not limit the scope of this disclosure to any particular implementation of a UE.

As shown in FIG. 3, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives, from the antenna 305, an incoming RF signal transmitted by a gNB of the network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the UE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 is also capable of executing other processes and programs resident in the memory 360. The processor 340 can move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350, which includes for example, a touchscreen, keypad, etc., and the display 355. The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3 illustrates the UE 116 configured as a mobile telephone or smartphone, UEs could be configured to operate as other types of mobile or stationary devices.

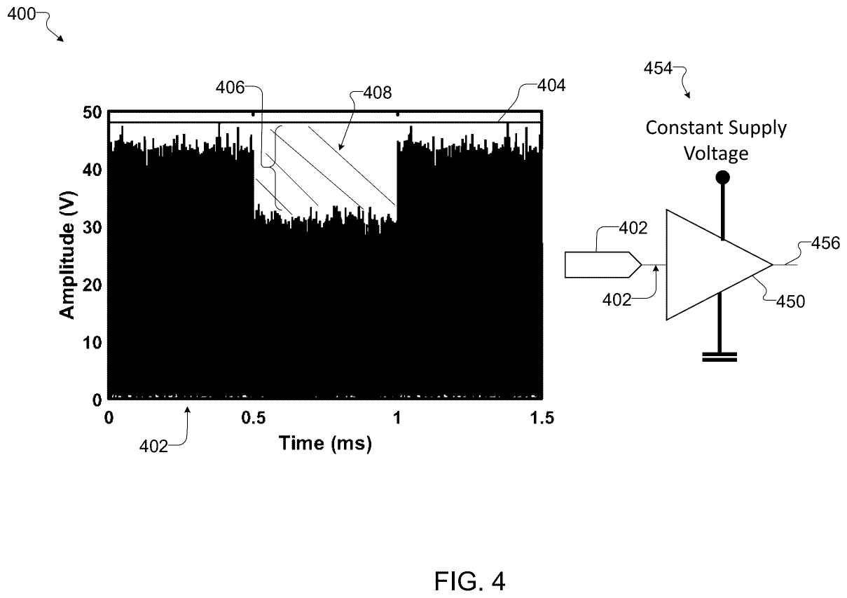

The TX processing circuitry of the gNB 101 may also include one or more power amplifiers coupled to one or more digital-to-analog converters and configured to amplify the baseband signal prior to transmission using the antenna. The one or more power amplifiers receive a supply voltage sufficient to cover the signal envelope of the baseband signal, as shown in FIG. 4.

FIG. 4 illustrates an example signal envelope 400 of a power amplifier 450. As shown in FIG. 4, the signal envelope 400, which may be represented as amplitude voltage over time, includes a RF envelope 402 representative of a baseband signal supplied to the power amplifier 450 from the DAC 452. In response to receiving the RF envelope 402, the power amplifier 450, using a constant supply voltage source 454 provides a PA supply voltage 404 to generate an output signal 456. The PA supply voltage 404 may need to have a voltage level (e.g., 48 volts as shown) greater than the RF envelope 402 to be effective. The RF envelope 402, however, fluctuates over time, creating a gap 406 between the RF envelope 402 and the PA supply voltage 404. The gap 406 creates an area of wasted energy 408 as the PA supply voltage 404 remains constant despite the RF envelope 402 changing voltage levels over time.

Further, the gap 406 forces the power amplifier 450 to operate in a power backoff mode. In a power backoff mode, the power amplifier 450 operates at a reduced power level below its maximum output, intentionally lowering the signal received from the DAC 452 to maintain linearity and avoid distortion, especially when dealing with signals that have large peaks in power, ensuring the power amplifier 450 stays within its linear operating region even during high signal bursts from the DAC 452. While operating in backoff mode can improve signal quality, it usually comes at the cost of reduced power efficiency as the power amplifier 450 is not operating at its peak power output. In particular, when the power amplifier 450 operates in a power backoff mode, its power added efficiency (PA E) typically decreases significantly, reducing the effectiveness of the power amplifier 450 in amplifying the RF envelope 402.

Although FIG. 4 illustrates one example of a signal envelope of a power amplifier, various changes may be made to FIG. 4. For example, the baseband signal may fluctuate between more than two voltage levels, such as between three or more voltage levels, such as between 4 or more voltage levels.

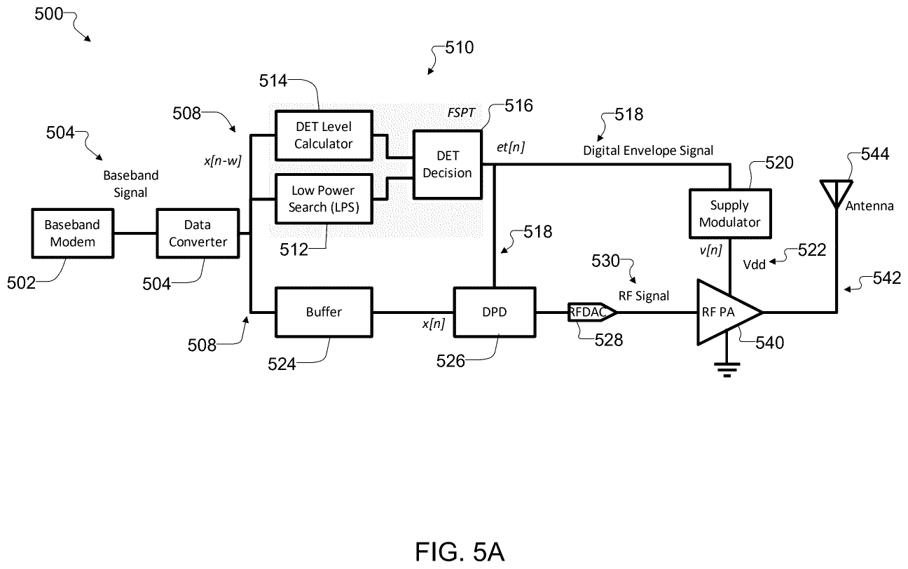

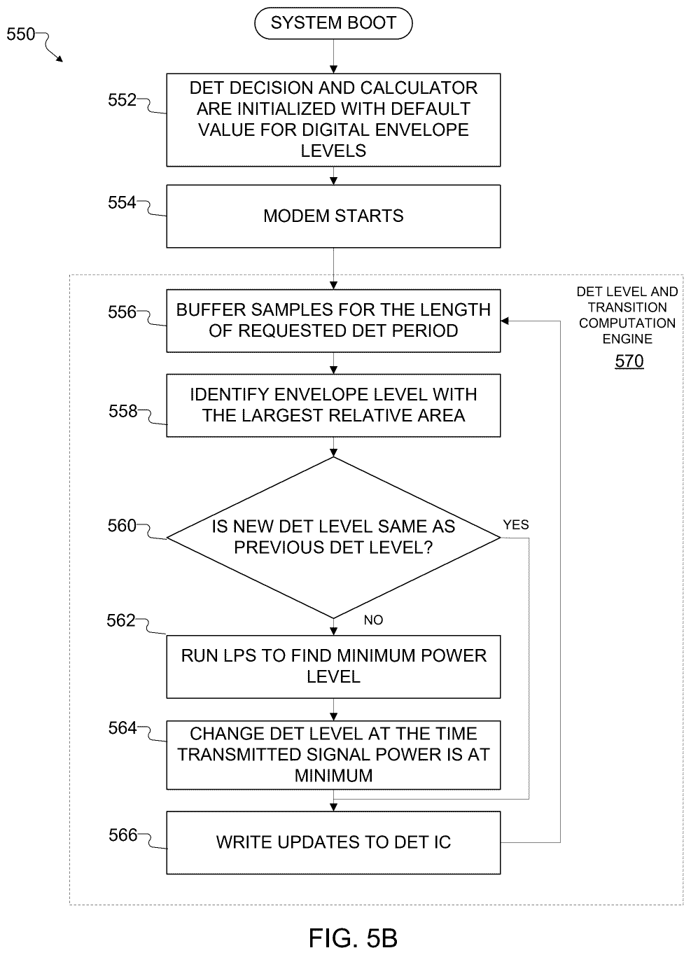

To improve power efficiency, the area of wasted energy 408 should be minimized between the RF envelope 402 and the PA supply voltage 404. This may be accomplished by addressing the challenges in PA nonlinearity compensation when using DET, for example, by adjusting supply voltages to the power amplifier based on a low power search algorithm over a window of baseband signals using a non-periodic digital envelope tracking system as shown in FIGS. 5A-5B.

FIG. 5A illustrates an example non-periodic digital envelope tracking system according to embodiments of the present disclosure. The embodiment of the non-periodic digital envelope tracking system 500 shown in FIG. 5A is for illustration only. Other embodiments of the non-periodic digital envelope tracking system 500 could be used without departing from the scope of this disclosure.

As shown in FIG. 5A, the non-periodic digital envelope tracking system 500 may include a baseband modem 502 that generates and delivers an input signal 504 to a data converter 506. The data converter 506 converts the input signal 504 into in-phase and quadrature (IQ) baseband data 508 from the input signal 504. The data converter 506 produces the IQ baseband data 508 through a data conversion process that includes digital up-conversion and filtering. The data converter 506 then provides the IQ baseband data 508 to a Faster-than-Symbol Power Tracking (FSPT) module 510.

The FSPT module 510 includes a low power search (LPS) module 512, a DET level calculator 514, and a DET decision module 516. A digital envelope signal 518 is generated by calculating the input signal amplitude level based on the IQ baseband data 508 in the DET level calculator 514 and an LPS algorithm in the LPS module 512 over a window of input signals 504. The DET levels (e.g., DET control bits) are propagated to the DET decision module 516. The FSPT module 510 then outputs a digital envelope signal 518 to a supply modulator 520. The supply modulator 520 receives the digital envelope signal 518 and generates voltage levels according to the digital envelope signal 518. The supply modulator 520 then supplies a supply voltage 522 to a power amplifier 540 based on the voltage levels generated.

The data converter 506 also transmits the input signal 504 to a buffer 524 which then provides the IQ baseband data 508 to a digital pre-distortion (DPD) module 526. The DPD module 526 generates a pre-distorted RF signal 530 and provides the RF signal 530 to the power amplifier 540 through a radio frequency digital-to-analog converter (RFDAC) 528, which converts the digital signal into an analog signal. The power amplifier 540 then uses the RF signal 530 and the supply voltage 522 to amplify the RF signal 530 and, subsequently, generate and provide an output signal 542 to an antenna 544.

The FSPT module 510 may use Symbol Power Tracking (SPT) to measure the peak power of samples in an orthogonal frequency-division multiplexing (OFDM) symbol of the IQ baseband data 508 and changes the power amplifier 540 voltage level uniformly at the cyclic prefix time of an OFDM symbol. Additionally, a DET frequency used by the FSPT module 510 may be faster than other SPT methods for further improved efficiency of the power amplifier 540. However, the supply modulator 520 may require support to switch between voltage levels faster while maintaining signal quality (e.g., having low signal distortion).

The below equation returns the expected power consumption P_{DC} (in Watt) of power amplifier 540 at the time t. The input and output power are Pᵢₙ and Pₒᵤₜ (in dBm). Also, the power amplifier 540 gain β (in dB) and PA power efficiency as α.

$${P}_{D C} = \frac{{10}^{( \frac{{P}_{o u t} - 30}{10} )}}{α} , {P}_{o u t} = β \times {P}_{i n} .$$

As shown above, power consumption of the power amplifier 540 changes exponentially with the power Pᵢₙ of the input signal 504. The LPS algorithm minimizes signal distortions in DET-based systems by shifting voltage levels (e.g., voltage levels provided by the FSPT module 510 and the supply modulator 520) when the transmitted signal power is low, which results in a faster transition time and a smaller over-shoot/under-shoot of the supply voltage 522 during a level change. The LPS algorithm forces transitions to happen when input signal power is at least a minimum over a window of time. Power switching in the supply modulator 520 has a transition and settling time that may need to be modeled for non-linearity compensation.

FIG. 5B illustrates an example flow chart for digital envelope tracking calculation 550 for the non-periodic digital envelope tracking system of FIG. 5A according to embodiments of the present disclosure. The embodiment of the digital envelope tracking calculation 550 shown in FIG. 5B is for illustration only. Other embodiments of the digital envelope tracking calculation 550 could be used without departing from the scope of this disclosure.

As shown in FIG. 5B, the digital envelope tracking calculation 550 of the non-periodic digital envelope tracking system 500 may be implemented by a DET level and transition computation engine 570 of the FSPT module 510 (e.g., within the DET decision module 516) and includes initializing the DET decision module and the DET level calculator with a predetermined or default value for digital envelopes (operation 552). After the modem starts (operation 554), the IQ baseband data 508 is buffered to determine the length of a requested DET period (e.g., a retention time) in operation 556.

For example, let x be the complex IQ baseband data 508 indexed by n. Let f represent the DET decision function that maps the nth baseband sample of x to a DET level l∈{1, 2, . . . , L} for a set of L voltage levels denoted by Vₗ. The DET level computation 550 is broken down to small packet processing indexed by the kth window with a retention time T_{w}, (e.g., window length) for each packet. Both the buffer 524 (e.g., as a moving average power calculator) and the DET level calculator 514 will buffer the retention time T_{w} of the input signal 504 where

$${T}_{w} = \frac{1}{{f}^{max}} .$$

The DET decision module 516 may consider realistic constraints, such as the minimum retention time T_{w}, at any level as well as a maximum transition time, Tₜᵣ, based on the IQ baseband data 508.

Subsequently, the envelope level with the largest relative area over the retention time is identified using the DET decision module 516 (operation 558). For example, to account for system constraints, the DET decision module 516 will, after the IQ baseband data 508 is buffered for the retention time T_{w}, determine a DET level for the kth window over the maximum value of each retention time T_{w}. The DET level is determined, for example, by:

$${V}_{l} [ k ] = {f ( max ( x [ i ] ) )}_{i = 1}^{T w} .$$

The DET decision module will determine if the newly calculated DET level is the same as a previous DET level (operation 560) or, if during an initial DET calculation, if the newly calculated DET level is the same as the default or predetermined DET level. For example, the DET decision module 516 verifies if the current calculated level Vₗ[k] is the same as a previous level Vₗ[k−1]. If the new DET level and the previous (or default) DET level are not the same, the FSPT module 510 (e.g., via the DET decision module 516) will initiate a transition DET level change.

If DET level change is initiated, for example, the LPS module 512 implements an LPS algorithm to determine a minimum power level of the input signal 504 (operation 562). In other words, the transition time will be set by the LPS module 512 at a time that the input signal 504 power P[j] is at a minimum, for example, where the LPS algorithm uses the below functions:

$$P [ j ] = {\sum }_{i = j}^{j + Ttr} \vert x [ i ] \vert j ∈ \{ 1 , 2 , … , {T}_{w} \} , and$$

$${V}_{l} [ k ] = {f ( max ( x [ i ] ) )}_{i = 1}^{T j} \vert {T}_{j} = arg min ( P [ j ] ) .$$

Once the minimum power level Vₗ of the IQ baseband data 508 is determined, a DET level change is transmitted (e.g., to the DET level calculator 514) during a time during the retention time T_{w} that the signal power P[j] of the input signal 504 is at a minimum.

After this, updates are written to the DET decision module (operation 566). Similarly, if the current calculated level and the previous level are the same (operation 560), the calculation 550 proceeds to operation 566 and the FSPT module 510 will buffer a subsequent instance of the IQ baseband data 508 using the DET level calculator 514.

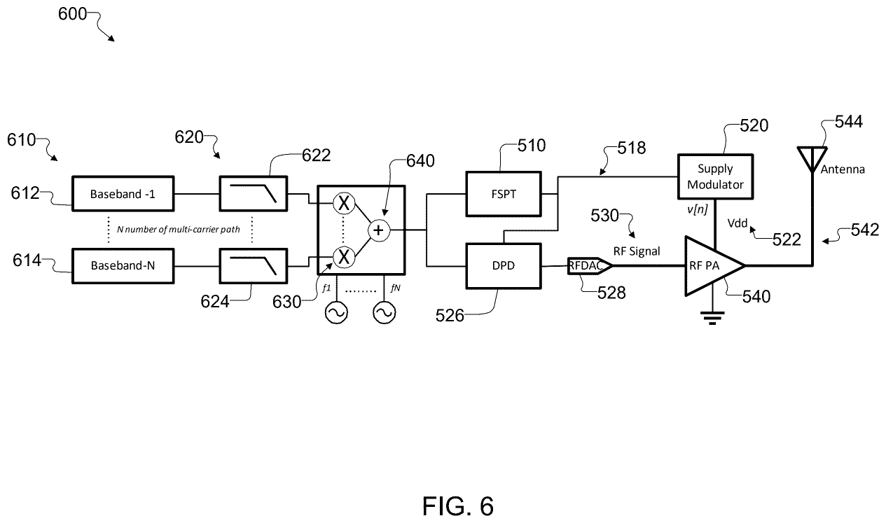

Although FIGS. 5A and 5B illustrate an example non-periodic digital envelope tracking system, various changes may be made to FIGS. 5A and 5B. For example, various components in FIGS. 5A and 5B could be combined, further subdivided, or omitted and additional components could be added according to particular needs. Also, the DPD module may include a neural network to generate the digital pre-distortion signal or the input signa may include a plurality of input signals, such as in a multi-carrier system as shown in FIG. 6.

FIG. 6 illustrates an example multi-carrier non-periodic digital envelope tracking system 600 according to embodiments of the present disclosure. The embodiment of the multi-carrier non-periodic digital envelope tracking system 600 shown in FIG. 6 is for illustration only. Other embodiments of the multi-carrier non-periodic digital envelope tracking system 600 could be used without departing from the scope of this disclosure. In particular, the multi-carrier non-periodic digital envelope tracking system 600 is configured similarly to the non-periodic digital envelope tracking system 500 of FIG. 5A except as otherwise described.

As shown in FIG. 6, the multi-carrier non-periodic digital envelope tracking system 600 may include a plurality of baseband input signals 610, such as a first baseband input signal 612 and a second baseband input signal 614. Each of the plurality of baseband input signals 610 may originate from a single modem (e.g., the baseband modem 502) or multiple modems. Each of the plurality of baseband input signals 610 may then be processed by a plurality of upsamplers 620. For example, the first baseband input signal 612 may be upsampled by a first upsampler 622 and the second baseband input signal 614 may be upsampled by a second upsampler 624. The upsampled plurality of baseband input signals 610 are then phase shifted by one or more phase shifters 630 and combined using one or more frequency multiplexors 640.

The combined plurality of baseband input signals 610 may then be used as input into the FSPT module 510 and the DPD module 526 for processing as described in FIGS. 5A and 5B, although the sampling frequency is higher and should match the component carrier-combining frequency.

Although FIG. 6 illustrates an example non-periodic digital envelope tracking system, various changes may be made to FIG. 6. For example, various components in FIG. 6 could be combined, further subdivided, or omitted and additional components could be added according to particular needs.

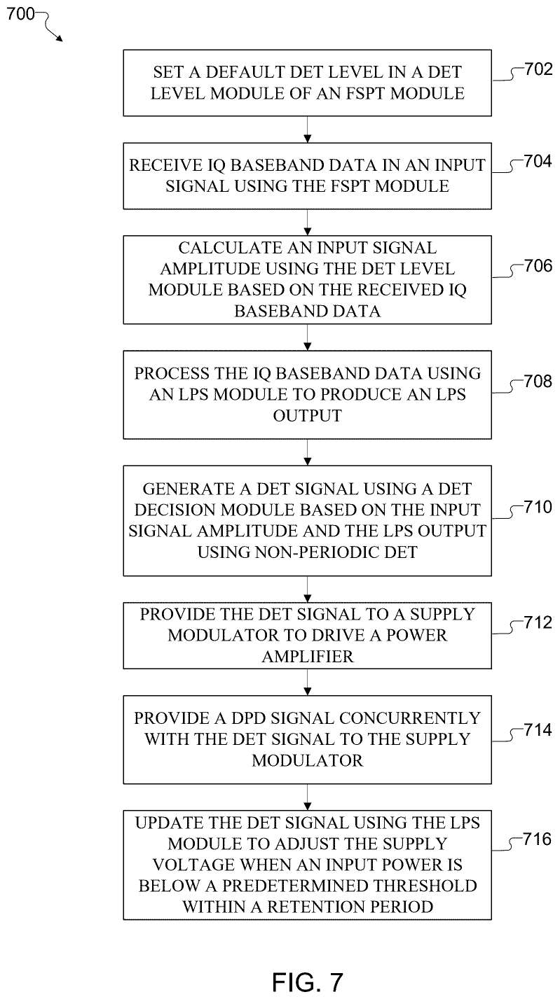

FIG. 7 illustrates an example method 700 of non-periodic digital envelope tracking according to embodiments of the present disclosure. An embodiment of the method illustrated in FIG. 7 is for illustration only. One or more of the components illustrated in FIG. 7 may be implemented in specialized circuitry configured to perform the noted functions or one or more of the components may be implemented by one or more processors executing instructions to perform the noted functions. Other embodiments of digital pre-distortion could be used without departing from the scope of this disclosure.

A default digital envelope tracking (DET) level is set in a DET level calculator 514 of a Faster-than-Symbol Power Tracking (FSPT) module 510 in step 702. For example, the DET level calculator 514 may include predetermined DET levels based on anticipated RF load scenarios or arbitrary levels.

In-phase and quadrature (IQ) baseband data 508 in an input signal 504 is received using the FSPT module 510 in step 704. For example, the baseband modem 502 may generate the input signal 504 (e.g., based on received RF signals) and deliver the input signal 504 to the data converter 506 to generate IQ baseband data 508 from the input signal 504. The data converter 506 may then deliver the IQ baseband data 508 to the FSPT module 510. Additionally, the IQ baseband data 508 is buffered to determine the length of a requested DET period (e.g., a retention time).

An input signal 504 amplitude is calculated using the DET level calculator 514 of the FSPT module 510 based on the received IQ baseband data 508 in step 706. Calculating the input signal 504 amplitude may include selecting an envelope level of a plurality of envelope levels of the input signal 504 amplitude within the retention period based on an envelope area then determining if a DET level of the received IQ baseband data 508 is the same as a previous DET level. For example, the envelope level with the largest relative area (e.g., the highest amplitude for a duration of the retention time) over the retention time is identified using the DET decision module 516 by determining a DET level for the kth window over the maximum value of each retention time T_{w}. The DET decision module will determine if the newly calculated DET level is the same as a previous DET level or, if during an initial DET calculation, if the newly calculated DET level is the same as the default or predetermined DET level.

The IQ baseband data 508 is processed using a low power search (LPS) module 512 of the FSPT module 510 to produce an LPS output in step 708. For example, upon determining that the DET level of the received IQ baseband data 508 is different than the previous DET level, the LPS module 512 may use the LPS algorithm to determine a minimum power level and produce the LPS output based on the determined minimum power level. The transition time will be set by the LPS module 512 at a time that the input signal 504 power is at a minimum. This will allow for DET level transitions to occur during a period that preserves output signal quality.

A DET signal is generated using a DET decision module 516 of the FSPT module 510 based on the input signal 504 amplitude and the LPS output in step 710. The DET decision module 516 configured to use non-periodic DET to generate the DET signal. The DET decision module 516 may update the DET level based on the LPS output. For example, the digital envelope signal 518 is generated by calculating the input signal amplitude level based on the IQ baseband data 508 in the DET level calculator 514 and the LPS algorithm in the LPS module 512 over a window of input signals 504. The DET control bits are propagated to the DET decision module 516 to drive the supply modulator 520.

The DET signal is provided to a supply modulator to drive the power amplifier step 712. For example, the supply modulator 520 may use the DET signal to select a corresponding supply voltage 522 to drive the power amplifier 540.

A digital pre-distortion signal is provided concurrently with the DET signal to the supply modulator in step 714. For example, the data converter 506 may provide the IQ baseband data 508 to the buffer 524 which subsequently provides the IQ baseband data 508 to the DPD module 526. The DPD module 526 may generate a digital pre-distortion signal using the IQ baseband data 508 and the digital envelope signal 518. The digital pre-distortion signal may then be provided to the power amplifier 540, along with the supply voltage 522, after conversion to an analog signal (e.g., using the RFDAC 528).

The DET signal is updated based on a DET decision using a low power search (LPS) algorithm of the LPS module 512 to adjust a supply voltage to the power amplifier when an input power of the IQ baseband data 508 is below a predetermined threshold within a retention period in step 716. For example, the FSPT module 510 may receive a subsequent instance of the IQ baseband data 508 (e.g., from subsequent input signals 504) that may require a DET level change as determined by the DET decision module 516, using steps 706-710.

Although FIG. 7 illustrates one example method 700 for non-periodic digital envelope tracking, various changes may be made to FIG. 7. For example, while shown as a series of steps, various steps in FIG. 7 could overlap, occur in parallel, occur in a different order, or occur any number of times. For example, the non-periodic digital envelope tracking system 500 may continuously repeat steps 710 through 716.

The above flowcharts illustrate example methods that may be implemented in accordance with the principles of the present disclosure and various changes could be made to the methods illustrated in the flowcharts herein. For example, while shown as a series of steps, various steps in each figure could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claims scope. The scope of patented subject matter is defined by the claims.

What is claimed is:

1. A method comprising:
setting a default digital envelope tracking (DET) level in a DET level module of a Faster-than-Symbol Power Tracking (FSPT) module;
receiving in-phase and quadrature (IQ) baseband data in an input signal using the FSPT module;
calculating an input signal amplitude using the DET level module of the FSPT module based on the received IQ baseband data;
processing the IQ baseband data using a low power search (LPS) module of the FSPT module to produce an LPS output;
generating a DET signal using a DET decision module of the FSPT module based on the input signal amplitude and the LPS output, the DET decision module configured to use non-periodic DET to generate the DET signal; and
providing the DET signal to a supply modulator to drive a power amplifier.

2. The method of claim 1, further comprising:
updating the DET signal based on a DET decision using a low power search (LPS) algorithm of the LPS module to adjust a supply voltage to the power amplifier when an input power of the IQ baseband data is below a predetermined threshold within a retention period.

3. The method of claim 2, wherein calculating an input signal amplitude using the DET level module of the FSPT module based on the received IQ baseband data comprises:
selecting an envelope level of a plurality of envelope levels of the input signal amplitude within a retention period based on an envelope area; and
determining if a DET level of the received IQ baseband data is the same as a previous DET level.

4. The method of claim 3, wherein processing the IQ baseband data using the LPS module of the FSPT module to produce the LPS output comprises upon determining that the DET level of the received IQ baseband data is different than the previous DET level, using the LPS algorithm to determine a minimum power level and produce the LPS output based on the determined minimum power level.

5. The method of claim 4, wherein generating a DET signal using the DET decision module of the FSPT module based on the input signal amplitude and the LPS output comprises updating the DET level in the DET decision module based on the LPS output.

6. The method of claim 1, further comprising:
providing a digital pre-distortion signal concurrently with the DET signal to the supply modulator.

7. The method of claim 6, wherein the digital pre-distortion signal is also provided to the power amplifier after conversion to an analog signal.

8. An electronic device, comprising:
a power amplifier; and
a processor operably coupled to the power amplifier and configured to cause the electronic device to:
set a default digital envelope tracking (DET) level in a DET level module of a Faster-than-Symbol Power Tracking (FSPT) module;
receive in-phase and quadrature (IQ) baseband data in an input signal using the FSPT module;
calculate an input signal amplitude using the DET level module of the FSPT module based on the received IQ baseband data;
process the IQ baseband data using a low power search (LPS) module of the FSPT module to produce an LPS output;
generate a DET signal using a DET decision module of the FSPT module based on the input signal amplitude and the LPS output, the DET decision module configured to use non-periodic DET to generate the DET signal; and
provide the DET signal to a supply modulator to drive the power amplifier.

9. The electronic device of claim 8, wherein the processor is further configured to cause the electronic device to:
update the DET signal based on a DET decision using a low power search (LPS) algorithm of the LPS module to adjust a supply voltage to the power amplifier when an input power of the IQ baseband data is below a predetermined threshold within a retention period.

10. The electronic device of claim 9, wherein, while causing the electronic device to calculate an input signal amplitude using the DET level module of the FSPT module based on the received IQ baseband data, the processor is further configured the electronic device to:
select an envelope level of a plurality of envelope levels of the input signal amplitude within a retention period based on an envelope area; and
determine if a DET level of the received IQ baseband data is the same as a previous DET level.

11. The electronic device of claim 10, wherein, while causing the electronic device to process the IQ baseband data using the LPS module of the FSPT module to produce the LPS output, the processor is further configured to cause the electronic device to, upon determining that the DET level of the received IQ baseband data is different than the previous DET level, use the LPS algorithm to determine a minimum power level and produce the LPS output based on the determined minimum power level.

12. The electronic device of claim 11, wherein, while causing the electronic device to generate a DET signal using the DET decision module of the FSPT module based on the input signal amplitude and the LPS output, the processor is further configured to cause the electronic device to update the DET level in the DET decision module based on the LPS output.

13. The electronic device of claim 8, the processor is further configured to cause the electronic device to:
provide a digital pre-distortion signal concurrently with the DET signal to the supply modulator.

14. The electronic device of claim 13, the processor is further configured to cause the electronic device to:
provide the digital pre-distortion signal to the power amplifier after conversion to an analog signal.

15. A non-transitory computer-readable medium comprising program code, that when executed by at least one processor of an electronic device, causes the electronic device to:
set a default digital envelope tracking (DET) level in a DET level module of a Faster-than-Symbol Power Tracking (FSPT) module;
receive in-phase and quadrature (IQ) baseband data in an input signal using the FSPT module;
calculate an input signal amplitude using the DET level module of the FSPT module based on the received IQ baseband data;
process the IQ baseband data using a low power search (LPS) module of the FSPT module to produce an LPS output;
generate a DET signal using a DET decision module of the FSPT module based on the input signal amplitude and the LPS output, the DET decision module configured to use non-periodic DET to generate the DET signal; and
provide the DET signal to a supply modulator to drive a power amplifier.

16. The non-transitory computer-readable medium of claim 15, further comprising program code, that when executed by the at least one processor of an electronic device, causes the electronic device to:
update the DET signal based on a DET decision using a low power search (LPS) algorithm of the LPS module to adjust a supply voltage to the power amplifier when an input power of the IQ baseband data is below a predetermined threshold within a retention period.

17. The non-transitory computer-readable medium of claim 16, wherein the program code, that when executed by the at least one processor, causes the electronic device to calculate an input signal amplitude using the DET level module of the FSPT module based on the received IQ baseband data, further comprises program code, that when executed by the at least one processor, causes the electronic device to:
select an envelope level of a plurality of envelope levels of the input signal amplitude within a retention period based on an envelope area; and
determine if a DET level of the received IQ baseband data is the same as a previous DET level.

18. The non-transitory computer-readable medium of claim 16, wherein the program code, that when executed by the at least one processor, causes the electronic device to process the IQ baseband data using the LPS module of the FSPT module to produce the LPS output, further comprises program code, that when executed by the at least one processor, causes the electronic device to:
upon determining that the DET level of the received IQ baseband data is different than a previous DET level, use the LPS algorithm to determine a minimum power level and produce the LPS output based on the determined minimum power level.

19. The non-transitory computer-readable medium of claim 18, wherein the program code, that when executed by the at least one processor, causes the electronic device to generate a DET signal using the DET decision module of the FSPT module based on the input signal amplitude and the LPS output, further comprises program code, that when executed by the at least one processor, causes the electronic device to:
update the DET level in the DET decision module based on the LPS output.

20. The non-transitory computer-readable medium of claim 15, further comprising program code, that when executed by the at least one processor of an electronic device, causes the electronic device to:
provide a digital pre-distortion signal concurrently with the DET signal to the supply modulator.
